(19) United States
(12) Patent Application Publication
(10) Pub. No.: US 2018/0083145 A1
(43) Pub. Date: Mar. 22, 2018

(54) Methods for Curing Anti-Reflective Coatings on Solar Glass

(71) Applicant: First Solar, Inc., Tempe, AZ (US)

(72) Inventors: Brian Cohen, Perrysburg, OH (US); David Hwang, Perrysburg, OH (US); Mark Lewis, Perrysburg, OH (US); Gopal Mor, Perrysburg, OH (US); Nathan Martin Schuh, Perrysburg, OH (US); Frank Xia, Perrysburg, OH (US); Yu Yang, Perrysburg, OH (US); Zhibo Zhao, Perrysburg, OH (US)

(73) Assignee: First Solar, Inc., Tempe, AZ (US)

(21) Appl. No.: 15/708,254

(22) Filed: Sep. 19, 2017

Related U.S. Application Data
(60) Provisional application No. 62/396,464, filed on Sep. 19, 2016.

(51) Int. Cl. H01L 31/0216; H01L 31/18

(52) U.S. Cl. CPC H01L 31/02168; H01L 31/18

(57) ABSTRACT

Methods of curing anti-reflective coatings, and photovoltaic modules produced using the methods, are described. The methods can include liquid metal curing, plasma curing, air knife curing, and flame curing.

### CROSS-REFERENCE TO RELATED APPLICATIONS

This application claims priority from U.S. Provisional Patent Application No. 62/396,464, filed on Sep. 19, 2016, which is incorporated by reference herein in its entirety.

### BACKGROUND

An anti-reflective coating (“ARC”) is a type of low reflectivity coating applied to the surface of a transparent article to reduce reflectance of visible light from the article and enhance the transmission of such light into or through the article. ARCs are useful in photovoltaic modules for such purposes. ARCs can include inorganic coatings made of titanium, titanium dioxide, titanium nitride, chromium oxide, carbon, or α-silicon, as well as organic coatings made of a light-absorbing substance and a polymer. ARCs can be deposited on the surface of glass supports by numerous methods, such as, but not limited to, the sol-gel method and vacuum deposition methods (known as conventional deposition, “CD”) in which the materials to be deposited are heated to a molten state, chemical vapor deposition (“CVD”), ion-assisted deposition (“IAD”) in which the film being deposited is bombarded with energetic ions of an inert gas during the deposition, and ion beam sputtering (“IBS”) in which an energetic beam is directed to a target material. Of these methods, the sol-gel method involves a low cost of materials and utilizes ambient pressures and temperatures. However, the sol-gel method generally requires curing in order to evaporate residual organics and other liquid components from the adhered layer, as well as to complete the matrix bonding, densify the coating structure, and make the coating robust against chemical attack and abrasion from hard particles. Under-cured films are subject to chemical decomposition. Both alkaline and ionic (salt) corrosion improve with higher temperature curing. Therefore, it would be advantageous to develop new and improved methods of curing antireflective coatings.

### BRIEF DESCRIPTION OF THE DRAWINGS

FIG. 1: Diagram of a non-limiting example of an antireflective coating in a photovoltaic module.

FIG. 2: Non-limiting illustration of a liquid metal curing process utilizing a solder wave.

FIG. 3: Non-limiting illustration of an air knife curing process.

FIG. 4: Non-limiting illustration of a plasma curing process with a plasma torch. The arrows depict the flow of gas.

FIGS. 5A-5B: Simulations showing the required time to reach curing temperature (FIG. 5A) and the maximum CdTe temperature (FIG. 5B) in a liquid metal curing method.

FIG. 6: Surface temperature simulation using various curing temperatures and durations, assuming a 3.2 mm glass thickness. The initial temperature was 20° C. in this simulation.

FIG. 7: Thermal simulation showing that heat “soaks in” to a glass/interlayer/glass module during a convection heating process. This simulation indicates that the faster the surface is heated, the less heat soaks in, and the greater the efficiency of the cure.

FIGS. 8A-8C: Temperature simulation of an air knife curing method on the glass surface temperature of a CdTe module (FIG. 8A) and the temperature of the inner device (FIG. 8B). FIG. 8C shows Table 1, displaying the surface temperatures, times-to-temperature, CdTe temperatures, and lengths. The arrows in FIGS. 8A-8B point to where the temperature of the ARC coating is 300° C.

FIG. 9: Simulation of air knife curing with a CdTe module, where the curve labeled “a” depicts the temperature of the glass surface and the curve labeled “b” depicts the temperature of the inner device.

FIG. 10: Graph showing improvements in abrasion resistance achieved by air knife curing. Films were cured by “parking” the air knife for different times (1-10 seconds) on uncured modules. The results show that ARC films can become at least 7 times stronger upong curing with an air knife.

FIG. 11: Graph showing abrasion data from an ARC cured by a liquid metal curing process. As seen in the graph, abrasion resistance improves upon curing an ARC with a liquid metal.

FIG. 12: Graph showing percent reflectance as a function of wavelength for two different ARCs cured by plasma curing before and after a post-manufacturing heat treatment (PMHT). As seen from the graph, the percent reflectance of both ARCs was reduced when the ARCs were cured via plasma curing after the PMHT compared to before the PMHT.

FIG. 13: Graph showing the percent reflectance as a function of wavelength for an uncured ARC control, an ARC cured with 4 passes of a plasma torch, an ARC cured with 8 passes of a plasma torch, and an ARC cured with 12 passes of a plasma torch. As seen from the graph, for much of the visible spectrum, the ARC cured with 4 passes of a plasma torch exhibited the lowest reflectance.

FIG. 14: Graph showing the percent reflectance as a function of wavelength for control ARCs and ARCs cured with varying numbers of passes with a plasma torch.

FIG. 15: Graph of film thickness versus spin speed for ARC-A following a thermal cure.

FIG. 16: Graph of % reflection reduction versus spin speed of an ARC.

FIG. 17: Graph of film thickness versus spin speed for ARC-B following a thermal cure.

FIG. 18: Graph of % reflection reduction versus spin speed for ARC-B.

FIG. 19: Graph of % transmission versus wavelength for ARCs following a thermal cure for 30 minutes at 285° C.

FIG. 20: Graph of % transmission versus wavelength for dilute spin coated ARCs following a thermal cure for 30 minutes at 285° C.

FIG. 21: Graph of plasma power density versus mapper velocity.

FIG. 22: Graph of % transmission versus wavelength as a function of curing for ARC films.

FIG. 23: Graph of % transmission versus wavelength as a function of curing for ARC films.

FIG. 24: Variability chart for J_{sc} comparing an ARC following no curing, plasma curing, and thermal curing. The J_{sc} values have been normalized relative to the uncoated/no cure devices.

FIGS. 25A-25B: SEM images of ARC-B following a thermal cure at 275° C. for 30 minutes (FIG. 25A) and plasma curing with 4 passes of a plasma torch (FIG. 25B).

FIGS. 26A-26B: SEM images of an ARC following a thermal cure at 275° C. for 30 minutes (FIG. 26A) and plasma curing with 4 passes of a plasma torch (FIG. 26B).

FIG. 27: Graph of contact angle as a function of cure and material, showing that plasma curing produces permanent super hydrophilic surfaces for some ARC films.

### DETAILED DESCRIPTION OF THE INVENTION

Throughout this disclosure, various publications, patents, and published patent specifications are referenced by an identifying citation. The disclosures of these publications, patents, and published patent specifications are hereby incorporated by reference into the present disclosure in their entirety to more fully describe the state of the art to which this invention pertains.

All ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, a state range of “1 to 10” should be considered to include any and all subranges beginning with a minimum value of 1 or more and ending with a maximum value of 10 or less, such as 1 to 3.3, 4.7 to 7.4, 5.5 to 10, and the like.

In the present disclosure, when a layer is described as being disposed or positioned “on” or “over” another layer or substrate, it is to be understood that the layers can either be directly contacting each other or have one (or more) layer or feature between the layers. Further, the terms “on” and “over” describe the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated. Likewise, a layer that is “disposed on” a different layer does not necessarily imply that the two layers are in direct contact with one another and may allow for the presence of intervening layers. In contrast, the term “adjacent” is used to imply that two layers are in direct physical contact. Furthermore, the terms “on top of,” “formed over,” “deposited over,” and “provided over” mean formed, deposited, provided, or located on a surface but not necessarily in direct contact with the surface. For example, a coating layer “formed over” a substrate does not preclude the presence of one or more other coating layers or films of the same or different composition located between the formed coating layer and the substrate.

Reference to an “interlayer” herein refers to the internal components of a photovoltaic module disposed underneath (in the case of a superstrate configuration) or on top of (in the case of a substrate configuration) a glass support. Such internal components may include, but are not limited to, any of a transparent conductive oxide layer, a buffer layer, a window layer, an absorber layer, and a back contact. It is understood that since the methods described herein are applicable to any type of photovoltaic module, the term “interlayer” as used herein is not limited to the components of a photovoltaic module based on a particular type of semiconductor (e.g., CdTe, crystalline Si, amorphous Si:H, GaAs, CIGS, etc.).

The term “transparent” as used herein refers to material that allows an average transmission of at least 70% of incident electromagnetic radiation having a wavelength in a range of from about 300 nm to about 850 nm.

The presence of an ARC can reduce light losses due to reflection in photovoltaics (such as CdTe-based photovoltaics), such that the efficiency of converting solar light into electrical energy can be enhanced. In photovoltaic module production, ARCs can be applied to the modules either at the front end of the line (FEOL) by coating the incoming glass, or at the back end of the line (BEOL) by forming the ARC layer on the finished modules. For FEOL ARCs, the fragile porous structure is usually subjected to the mechanical, thermal, and chemical impacts during the photovoltaic device fabrication, which may cause yield loss due to cosmetic defects, degradation of ARC performance, and module efficiency drop. BEOL ARC, on the other hand, is applied to the finished modules to avoid such harsh CdTe module manufacturing processes, but the ARC should still be cured to gain sufficient mechanical strength and durability.

Conventionally, BEOL ARC films are deposited when the module fabrication is almost completed. However, the exposure to high temperatures involved in curing, and the duration of such exposure, is a concern for device integrity. The curing of an ARC is usually carried out at a temperature ranging from 250° C. to 650° C., depending on the material, and sometimes requires long curing times (˜30-120 minutes), especially when cured at low temperatures. The elevated temperature for curing can result in damage to a finished photovoltaic (e.g., CdTe) module, especially to the encapsulant (such as ethyl vinyl acetate or polyolefin) layer and cord plate, and degrade photovoltaic module performance and reliability. Thus, in accordance with the present disclosure, the curing process should be accomplished without significantly raising the temperature underneath the glass and without affecting the device performance.

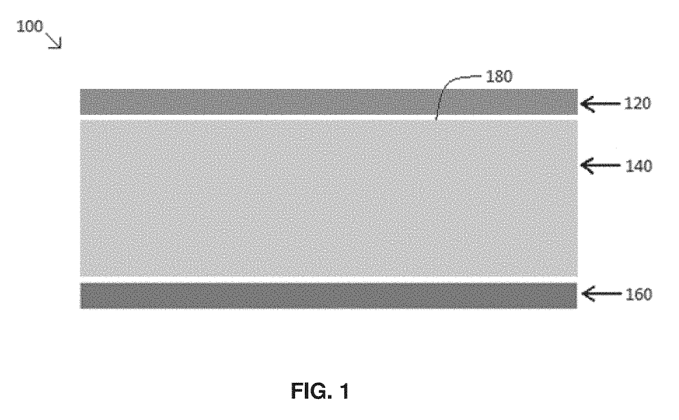

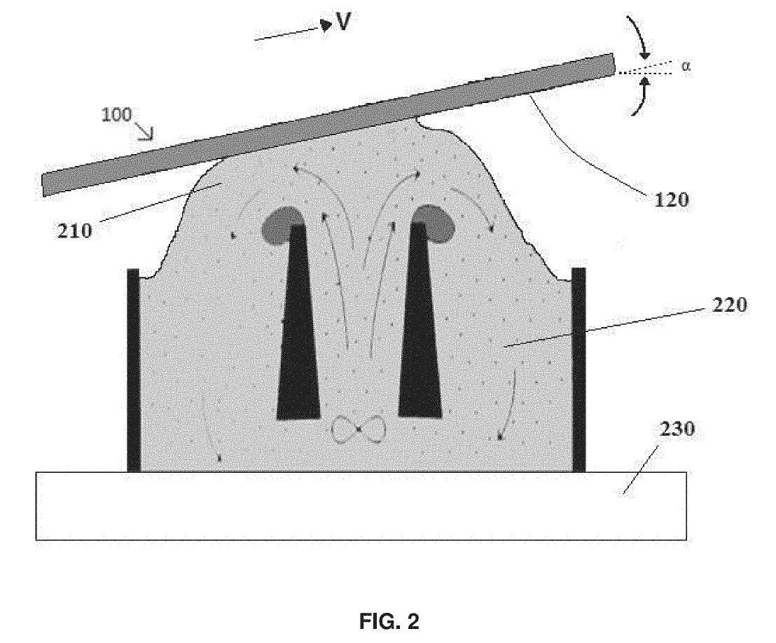

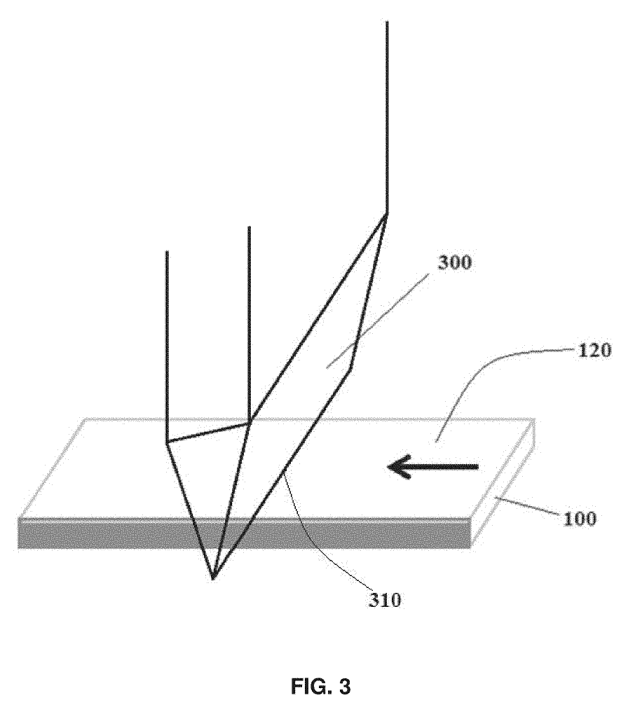

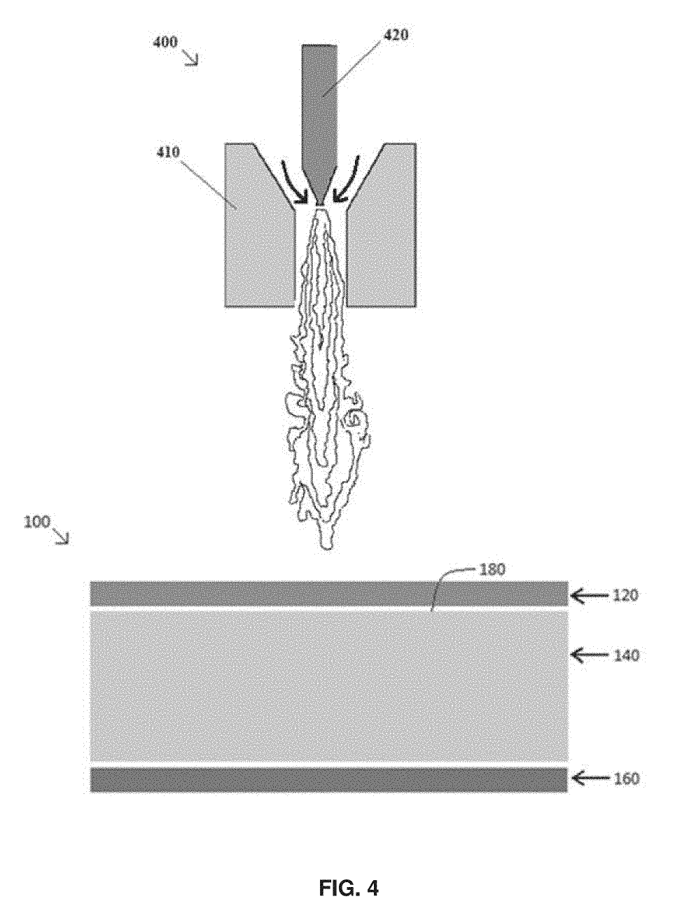

Provided herein are methods for curing ARCs such as, but not limited to, ARCs on glass supports used in photovoltaic modules. For example, provided are methods of curing an ARC on the sunny side of a TCO-coated superstrate glass having a preformed thin film PV module thereon. Also provided are methods of curing an ARC on the sunny side of a TCO-coated superstrate prior to forming a thin film PV module thereon. The methods of curing ARCs described herein include liquid metal curing (FIG. 2), air knife curing (FIG. 3), plasma curing (FIG. 4), and flame curing. Also provided are photovoltaic modules (FIG. 1) having ARCs cured by the methods described. These methods utilize a variety of different techniques, but all generally accomplish the removal of hydrocarbons from the ARC so as to cure the ARC. By burning away organic components trapped in the pores of the ARC, the refractive index of the ARC can be reduced, and the antireflective properties of the ARC can be improved. This results in more power produced by the photovoltaic modules containing the cured ARCs.

The curing methods herein are described with reference to sol-gel ARCs for exemplary purposes. The sol-gel method is a versatile low-temperature solution process for making inorganic ceramic and glass materials. In general, the sol-gel method involves the transition of a system from a liquid “sol” (mostly colloidal) into a solid “gel” phase. The starting materials used in the preparation of the “sol” are usually alkoxides. In a typical sol-gel method, the precursor is subjected to a series of hydrolysis and condensation polymerization reactions to form a colloidal suspension, or a “sol.” Hydrolysis of an alkoxide liberates alcohol and results in polymerized chains of metal hydroxide. For example, silica gels can be formed by hydrolysis of tetraethoxysilicate, Si(OC₂H₅)₄, based on the formation of silicon dioxide, SiO₂, and ethyl alcohol, C₂H₅OH. The gel coating is then cured to remove the liquid phase and leave a strongly crosslinked solid material (when properly cured), which may be porous. This sol-gel method is valuable for the development of coatings because it is easy to implement and provides films of generally uniform composition and thickness.

Most sol-gel antireflective coatings are cured by exposure to high temperature in an infrared or convection oven, and are often applied to raw glass at the beginning of the PV module manufacturing process. A conventional sol-gel curing process takes several minutes and works best at around 600° C. Upon curing, the sol-gel coatings become much harder, but are still prone to scratching and other damage in transport through manufacturing processes. As discussed above, it would therefore be ideal to apply a sol-gel antireflective coating at the end of the module manufacturing process. However, the interlayer of a photovoltaic module conducts a significant amount of heat to the back glass, and as a result, the high temperatures involved with conventional curing techniques, such as the high temperatures (e.g., 200-400° C.) attained in an oven, would destroy a finished module and damage module packaging. Some coatings can be cured at a temperature below 200° C. (such as about 120° C.) for about 1 hour, and are thus feasibly compatible with application to finished modules. However, the long process time for these curing processes requires a large, complex oven. Also, coatings cured at low temperature are not quite as strong as their high-temperature-cured counterparts. Therefore, it has been thought that applying an antireflective coating to a finished photovoltaic module would require a lower temperature cure process.

In some embodiments, the methods of curing an ARC described herein limit the duration of high glass surface temperature, thereby minimizing the risk to the photovoltaic module packaging and internal components. In some embodiments, the methods herein are “skinheating” processes which cure the top thin ARC on the sunny side of the glass at a high temperature in a short time while maintaining the temperature of the underneath photovoltaic structure below 120° C. In general, the faster the ARC-coated surface is heated, the less heat soaks into the glass, and the greater the efficiency of the cure. An ARC cured with a high peak energy for a short time can become several times stronger than an ARC cured through other methods. By way of non-limiting examples, the cured coating may have twice or three-times the hardness as the uncured coating.

In accordance with the present disclosure, various methods of curing can cause an ARC on a glass surface to be cured without significantly increasing the temperature of the underlying glass, or, in the case of a glass support in a photovoltaic module, without significantly increasing the temperature of the internal device. In general, the curing methods herein heat the ARC sufficient to cure the coating, such as to a temperature of about 300° C., while leaving the underlying glass temperature significantly lower. When conducted on a finished photovoltaic module, the temperature of the internal device is significantly lower than the temperature of the glass surface. The ratio of the peak glass surface temperature to the peak inner device temperature can range from about 2:1 to about 50:1, or from about 3:1 to about 10:1. In one non-limiting example, the ratio of the peak glass surface temperature to the peak inner device temperature is about 5:1. In certain embodiments, the curing method cures the ARC in an exposure time period (i.e., the duration of exposure to a liquid metal, a plasma, hot air from an air knife, or a flame) that is too short to significantly increase the temperature of the internal device. However, it is understood that any of the curing methods described herein are useful to cure ARCs on glass surfaces in isolation—that is, in the absence of photolvaic modules. Thus, provided herein are methods of curing ARCs on glass, regardless of whether the glass is a glass support of a photovoltaic module.

Without wishing to be bound by theory, it is believed that ARC film thickness and porosity are the two important parameters to achieve the best anti-reflectance property in the films. The thickness can be controlled by spin casting the films at different rpms. To achieve controlled porosity, it is desired to break down the organic molecules at a fast rate without raising the film-side temperature. The methods herein break down organic molecules in order to cure the ARC film. Though the methods herein utilize different physical means for achieving a cure, all the methods do so to remove the hydrocarbons from an ARC disposed on a glass surface (which may or may not be the glass support of a photovoltaic module) to cure the ARC without damaging any module components underneath the glass. Thus, when used on photovoltaic modules, the methods described herein permit high-temperature curing of the ARCs or other thin films while leaving most of the underlying support at a lower temperature and delivering little thermal exposure to the semiconductor and interlayer. This allows for coatings composed of, for example, nanoporous silicon dioxide, to be sintered together or otherwise cured, resulting in greater strength and ease of integration into thermally sensitive PV manufacturing processes.

Liquid Metal

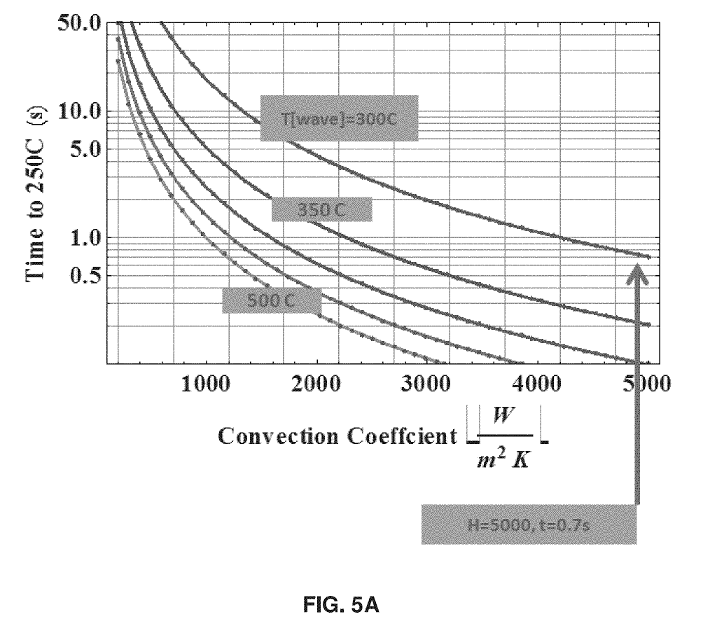

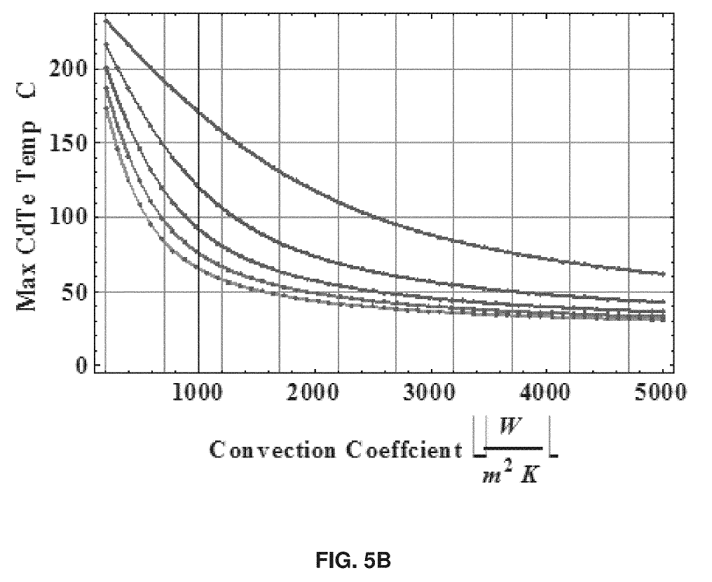

In accordance with the present disclosure, one solution to the curing problem is to use a heat transfer fluid with high density, low viscosity, and good thermal conductivity. Thus, in one embodiment, a liquid metal, such as a molten solder, can be used to rapidly cure ARCs. Without wishing to be bound by theory, it is believed this is possible due to the tremendous convection coefficient possible in a liquid metal. The convection coefficient, also known as the heat transfer coefficient, is the proportionality coefficient between the heat flux and the thermodynamic driving force for the flow of heat. The convection coefficient is denoted by the letter “H” in FIGS. 5A, 7, and 8A-8B.

Heat transfer from a liquid metal can deliver convection coefficients of greater than 5000 W/m²K at flow velocities of only a few cm/s. Since the convection coefficient for contact with a liquid metal is so high (4000-10000 W/m²K), only very brief contact is required to attain high temperature. A surface temperature of about 300° C. is important to cure the ARC. The resulting photovoltaic module exits the process relatively cool, having a surface temperature of about 70° C. The ARC on the glass is typically at least two times tougher following contact with the liquid metal.

An illustration of a liquid metal curing process using a solder wave is shown in FIG. 2. As depicted in FIG. 2, the antireflective coating layer 120 of the photovoltaic module 100 is contacted with a solder wave 210 at an angle α. In some embodiments, the angle α ranges from about 5 degrees to about 45 degrees relative to the horizontal. The photovoltaic module moves in a direction V across the wave 210 at the angle α. The solder wave 210 is created by circulating the solder in a solder reservoir 220 via a pump 230. The contact can occur, for instance, inside a soldering station. A modular soldering station can be used for this process, which may have one or more preheat stations for IR or hot air convection. The preheat stations can be used to increase the surface temperature of the glass prior to contacting the glass with the liquid metal. Various modular wave soldering systems are commercially available and suitable to accomplish liquid metal curing.

In one non-limiting example, a photovoltaic module's downward-facing ARC-coated glass surface is exposed to glancing contact (for instance, 1 second or less) with a ripple (wave) of solder flowing below it. This effectively pulls the glass surface temperature up to that of the liquid metal for nearly the duration of the contact. The glancing contact can last for a time period of from about 0.1 seconds to about 60 seconds, or from about 0.5 seconds to about 50 seconds, or from about 0.7 seconds to about 3 seconds. In one non-limiting example, the glancing contact lasts for about 1 second. FIGS. 5A-5B show the results of a simulation depicting the time of the liquid metal contact required to reach curing temperature and the maximum CdTe temperature.

In certain embodiments, the solder wave method involves brief contact with a pure tin bath at a temperature over 700° C. Thus, the solder wave method can be used to cure ARCs which require brief exposure to temperatures greater than 500° C., as some commercially available ARCs do. These ARCs display high optical performance, abrasion resistance, and chemical strength. However, liquid metal at temperatures other than 700° C. can be used. The liquid metal temperature can range from about 500° C. to about 900° C., or from about 650° C. to about 750° C. It is understood that the liquid metal temperature depends in part on the identity of the liquid metal. Though pure tin is described for exemplary purposes, many other liquid metals can be utilized. Suitable liquid metals include, but are not limited to: binary eutectic solders such as Sn/Ag, Sn/Sb, Sn/In, Sn/Zn, and Sn/Bi; ternary eutectic solders such as Sn/Pb/Ag, Sn/Bi/Sb, Sn/Ag/Cu, and Sn/Bi/In; near-eutectic solders such as compositions in which the minority element varies up to about 20% from that of the eutectic solder; and combinations thereof.

In some embodiments, the liquid metal curing is conducted in the absence of oxygen. When conducted in the presence of oxygen, certain liquid metals can oxidize and and deposit oxides such as tin oxide onto the glass surface. Therefore, in some embodiments, the liquid metal curing is conducted in an inert atmosphere. Suitable inert atmospheres include, but are not limited to, nitrogen, helium, argon, and combinations thereof.

In certain embodiments, the method leaves no solder or other liquid metal on the module. The hot metal is reciruclated, so the only energy required is that delivered to the glass. Because the metal can be continuously recirculated, this method can be more efficient than other methods given that there is no wasted hot air blowing away. The liquid metal curing method has an added advantage of requiring less power than other methods of curing ARCs. This is due in part to the recirculation of the liquid metal. Therefore, liquid metal curing is especially suitable for large scale production of complete photovoltaic modules with cured ARCs.

Air Knife

In another embodiment, an ARC is cured by passing the ARC-coated glass through a hot air knife, where hot air is blown toward the surface of the ARC-coated glass at a sufficient temperature, speed, and duration to cure the ARC on the glass. The air flow from an air knife is generally a high-intensity laminar flow of pressurized air. The air knife process is a high velocity convection process. In order to achieve a sufficient velocity of air, multiple air knife sets can be employed.

The air knife method is depicted in FIG. 3, where the arrow depicts the movement of the photovoltaic module 100 below the air knife 300. A photovoltaic module 100 passes under the air knife 300 such that the ARC coating layer 120 is directly exposed to the hot air blown through the nozzle 310 of the air knife 300. In an exemplary process, after coating a finished photovoltaic module with a thin (such as ˜100-150 nm) ARC layer, the photovoltaic module is passed through a hot air knife of ˜2-20 mm wide across the full width of the module. The ARC coating is cured by the hot air blown on it through the air knife while passing below it.

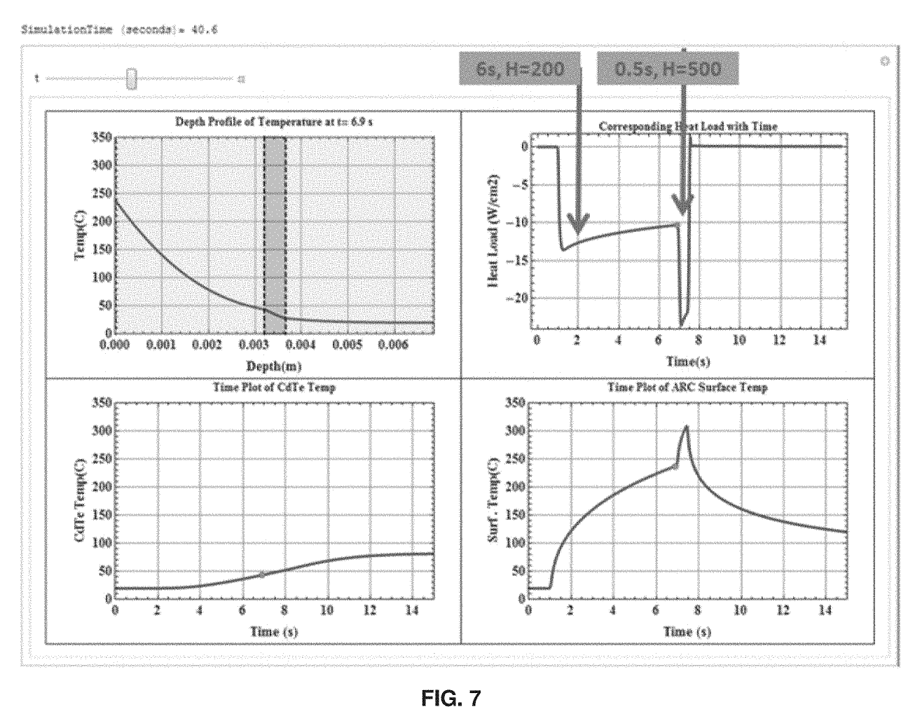

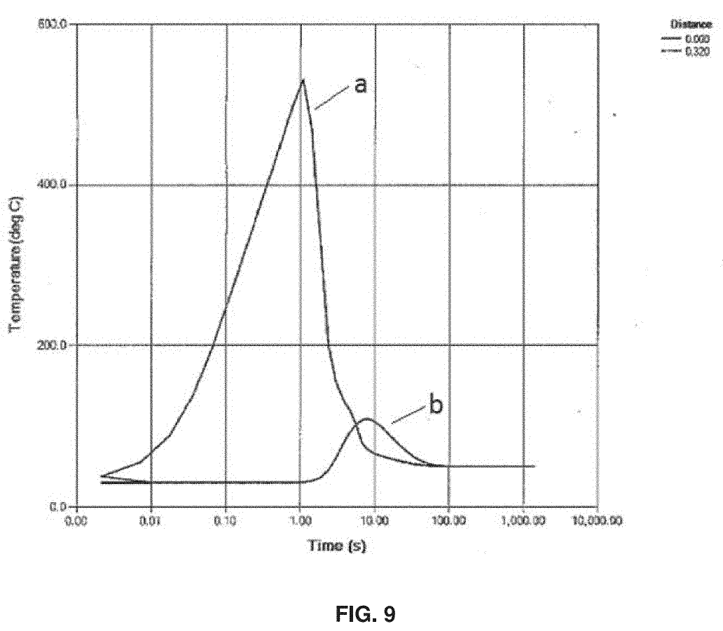

In general, the faster the surface is heated with the air knife, the less heat soaks into the glass, and the greater the efficiency of the cure. (FIG. 7.) The air knife method can quickly heat and cool the ARC films. Using an air knife, the surface of ARC-coated glass can reach over 300° C. FIG. 9 shows a simulation of air knife curing with a CdTe module, where the curve labeled “a” depicts the temperature of the glass surface and the curve labeled “b” depicts the temperature of the inner device. As seen in FIG. 9, the ratio of the peak glass surface temperature to the peak inner device temperature is about 5:1. Moreover, in the time it takes to reach the peak glass surface temperature, the inner device temperature is not substantially changed. As seen from the “b” curve in FIG. 9, the temperature of the inner device begins to increase only after a one-second exposure to the hot air from the air knife.

The air flow velocity, air temperature, module moving speed, and height of the air knife above the glass surface can all be optimized so as to allow a single passage lasting less than one minute (˜1-60 seconds) to cure the ARC layer on the glass. The air temperature can range from about 300° C. to about 900° C., or from about 500° C. to about 750° C. In one non-limiting example, the temperature of hot air blown by the air knife is about 650° C. The velocity of air flow can range from about 4,000 ft/min to about 40,000 ft/min, or from about 16,000 ft/min to about 32,000 ft/min. The module moving speed is set such that the module is exposed to the air knife for a time period ranging from about 1 second to about 60 seconds, or from 1 second to about 10 seconds, or from about 2 seconds to about 5 seconds. In non-limiting example, the module moving speed is set such that the module is exposed to the air knife for a time period of about 3 seconds. The height of the air knife above the glass surface can range from about 0.01 cm to about 1 m, or from about 0.1 cm to about 50 cm, or from about 1 cm to about 25 cm.

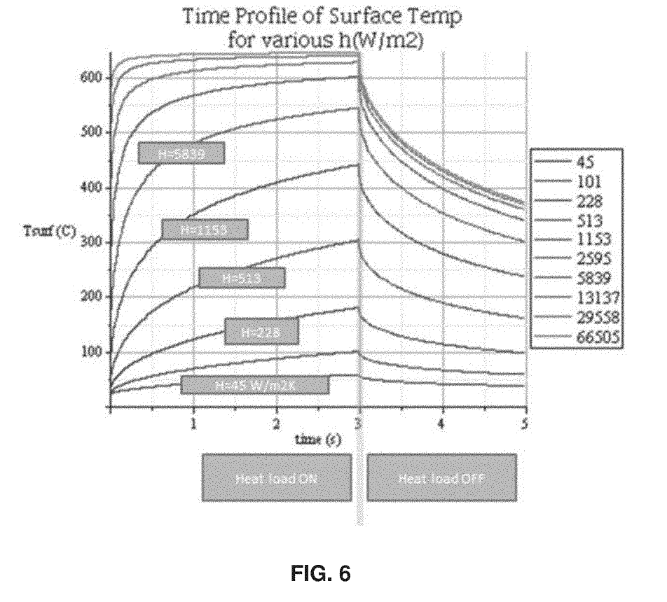

FIG. 6 depicts a simulation of the surface temperature of glass using various curing temperatures and durations, assuming a 3.2 mm glass thickness. (Note: in this simulation, the initial temperature is 20° C.) As seen in FIG. 6, a three-second pulse with hot air having a convection coefficient of H=513 W/m²K leads to a surface temperature of about 300° C. A typical convection coefficient for fast-flowing air is between about 200-400 W/m²K. The air temperature in this simulation is 650° C. This demonstrates that the temperature is sufficiently high for curing a top thin ARC layer while minimizing the thermal impact on an underlying photovoltaic device.

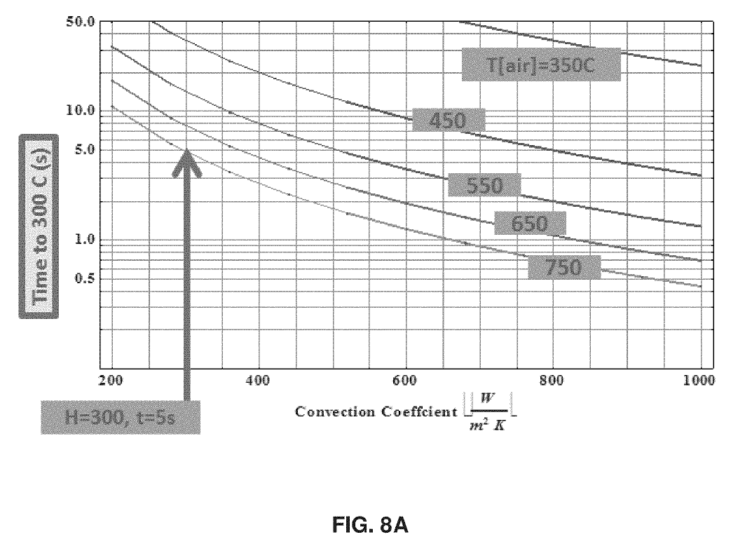

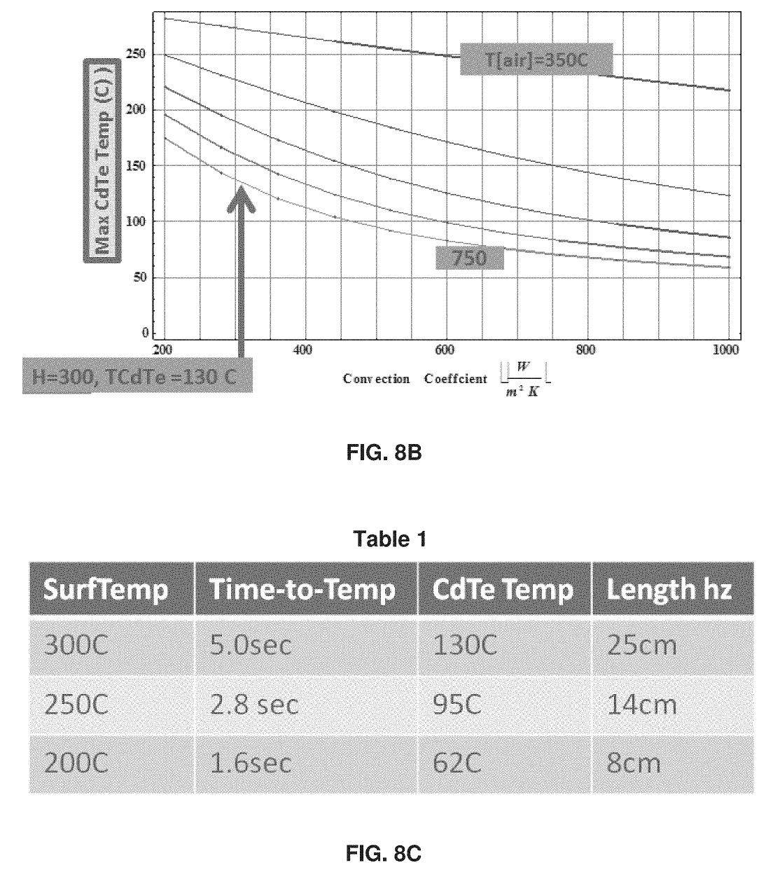

Using a 1D semi-infinite space approximation, a fairly accurate map of times required to obtain a surface temperature of 300° C. was generated. (FIG. 8A.) These maps are accurate for treatment times less than about 6 seconds. A similar map was generated for the maximum CdTe temperature by assuming the interlayer is a good insulator. (FIGS. 8B-8C.) Without wishing to be bound by theory, it is believed this is a conservative approximation.

The air knife method has the advantages of high productivity, lower investments, and requiring only limited floor space because of its unique simple structure and very short curing processing time. The air knife method can also be utilized for other photovoltaic applications, such as, but not limited to, curing anti-soiling coatings or anti-abrasion coatings.

Flame Curing

By exposing ARCs on glass surfaces to fast-moving hot air, the surface temperature is raised significantly above that of the underlying substrate. This can cure the ARC while minimizing thermal damage to components on the other side (such as an interlayer, etc.) compared to a conventional convection or IR oven. Thus, in one embodiment, a high velocity impinging flame is used to cure the ARC. Through the use of a high velocity impinging flame, sufficiently high surface temperatures to cure sol-gel ARCs can be obtained without breaking the underlying PV module glass. Brief exposure to a flame is enough to cure the ARC. A high velocity impinging flame can be created by a suitable burner, such as those capable of high-velocity oxygen injection. A plurality of flames can be utilized to cure ARCs on an array of modules at once. Similarly, a single ARC can be exposed to multiple passes of a flame.

In curing methods that involve the use of electrically heated hot air blowers, the degree to which the surface temperature exceeds that of the bulk is determined by the convection coefficient of the flowing air stream and the difference between its temperature and that of the glass. Maximizing the convection coefficient and temperature minimizes the time required to reach a given surface temperature, thereby limiting the heat deposited in the glass, and decreasing risk of damage to module packaging. The temperature of air delivered by an electric heater is limited to about 1000° C. and convection coefficient to a few hundred W/m²K. By the time the glass surface reaches target temperature of about 300° C., too much heat has been delivered to the glass and the risk of breakage is high. Using a flame in place of hot air (from a propane, MAPP gas, acetylene torch, or the like) permits air temperatures of 2000° C. or more and dramatically increases the convection coefficient as heat is generated within the impinging stream. Flame curing is therefore a faster alternative to hot air convection curing which additionally permits increased surface temperatures during processing. Additionally, an ARC cured with a high peak energy for a short time, such as a brief exposure to a flame, can become several times stronger than an ARC cured through other methods.

Plasma Curing

In another embodiment, plasma, such as from a plasma torch, is used for curing an ARC film. Plasma in general is an electrically neutral, and electrically conductive, medium containing unbound positive and negative particles. Plasma can be created in many ways, such as by subjecting a gas to a strong electromagnetic field. A plasma torch is a device configured to deliver a directed flow of plasma. A plasma torch can release a plasma jet having a temperature up to several thousands of degrees Celsius, and at a velocity of up to about 600 m/sec.

Plasma torches can be made using a continuous electric discharge (also known as an “electric arc”) in the presence of a carrier gas, such as nitrogen or argon, with, for instance, DC current. DC current plasma torches are described for exemplary purposes, though it is understood that plasma can be generated using AC current, radio frequencies, or other discharges. In general, the electric arc is formed between two electrodes, which can be made of metals such as copper, tungsten, graphite, molybdenum, silver, or the like. Suitable DC current plasma torches include both non-transferred arc torches, comprising an upstream electrode and a downstream electrode, and transferred arc torches, comprising only one electrode (the other electrode being outside the torch). In non-transferred arc torches, the electrical potential is contained entirely within the plasma torch, such as between two coaxial rings such that an electrical arc form in the annular space between the coaxial rings. A gas is passed through the annular area and emitted from the end of the torch. Suitable plasma gases include, but are not limited to, nitrogen, argon, and air. In transferred arc torches, the torch acts as one side of the electrical field and the other side of the field is exterior to, and spaced apart from, the torch. Transferred arc torches are generally more efficient, and capable of attaining higher operating temperatures, than non-transferred arc torches. Suitable plasma torches also include those having diaphragms disposed between the arc cathode and anode in order to stabilize the plasma of the electric arc.

FIG. 4 illustrates a plasma curing process using a plasma torch. As shown in FIG. 4, the photovoltaic module 100 is passed underneath a plasma torch 400 such that the ARC layer 120 is exposed to the plasma flame produced from anode 410 and cathode 420. The arrows depict the flow of the carrier gas. For illustrative purposes, FIG. 4 depicts a simple non-transferred arc plasma torch, but it is understood that transferred arc plasma torches work to cure ARCs in a similar manner. The distance between the plasma torch and the glass surface can range from about 0.01 mm to about 50 cm, or from about 1 mm to about 10 cm, or from about 2 mm to about 10 mm. In one non-limiting example, the distance between the plasma torch and the glass surface is about 6 mm.

The use of plasma can allow for ARC curing without raising device temperature beyond 100° C. Plasma curing of antireflective coatings is so easily and quickly accomplished that it is useful to replace ARCs not only in a manufacturing setting, but also in the field. In accordance with the present disclosure, plasma curing can be utilized on existing modules in the field, by coating the module glass with an ARC and then using a portable plasma torch to cure the ARC on the module glass in the field. Thus, plasma curing is a solution to the problem of ARCs soiling on existing modules. Furthermore, in certain embodiments, plasma curing results in cured ARCs having excellent anti-reflectance properties.

As described above, the breakdown of organic molecules at a fast rate without raising the film-side temperature results in better anti-reflectance properties of ARC films. Without wishing to be bound by theory, it is believed that plasma can break down and/or completely evaporate high molecular weight organic molecules, resins, or additives present in ARC solutions. Therefore, plasma curing can result in superior anti-reflectance properties in the resulting cured ARC.

A plasma torch works in the best way where nozzles of the plasma flame can be moved up and down in order to cover the whole film to be cured. When the process is repeated a few times, the lowest reflectance value over the desired spectrum wavelength range can be achieved. Therefore, certain embodiments of the plasma curing method include repeating the exposure step one or more times. As shown in the examples herein, only the optimal number of passes is required to cure; excessive passes may deteriorate the anti-reflectance property. The duration of the plasma treatment is therefore important. In one non-limiting example, four passes at a pass rate of one-inch per second is used to cure an ARC.

For a module, an array of plasma torches can be used to cover the plasma annealing along the whole width of the module. By moving the plasma torches forward and backward, a desired number of passes can be achieved to cure the films without raising the film-side temperature.

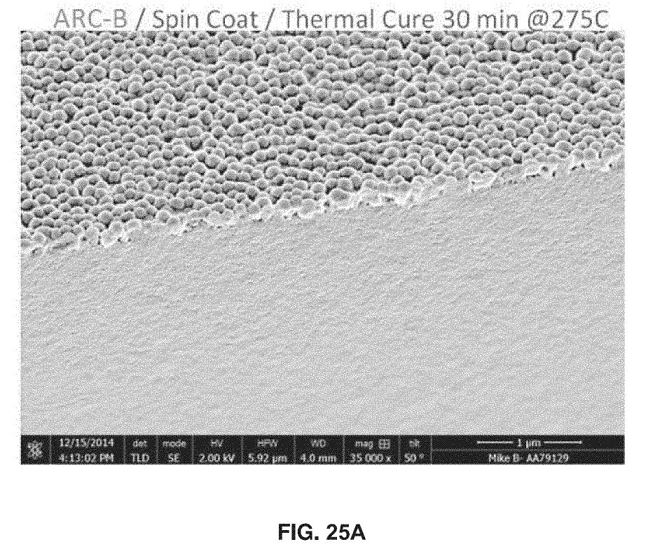

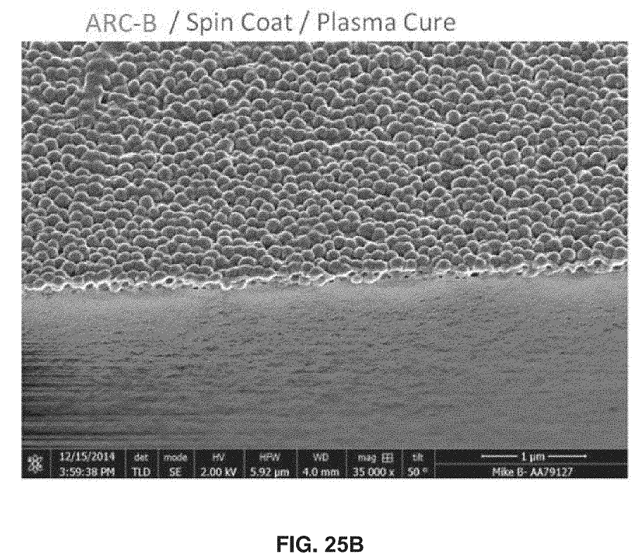

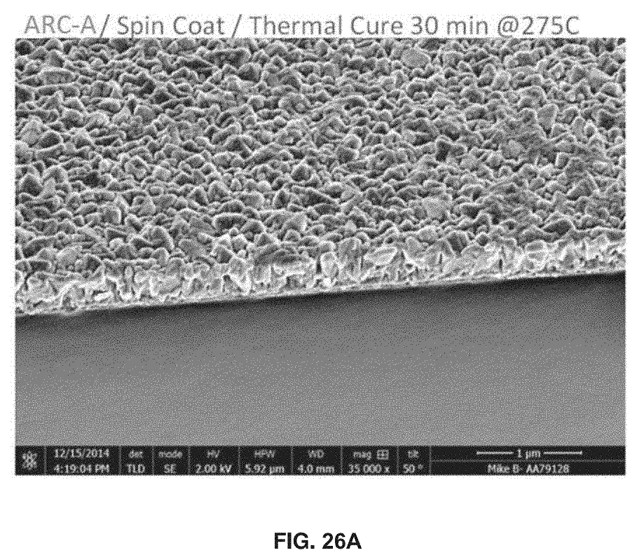

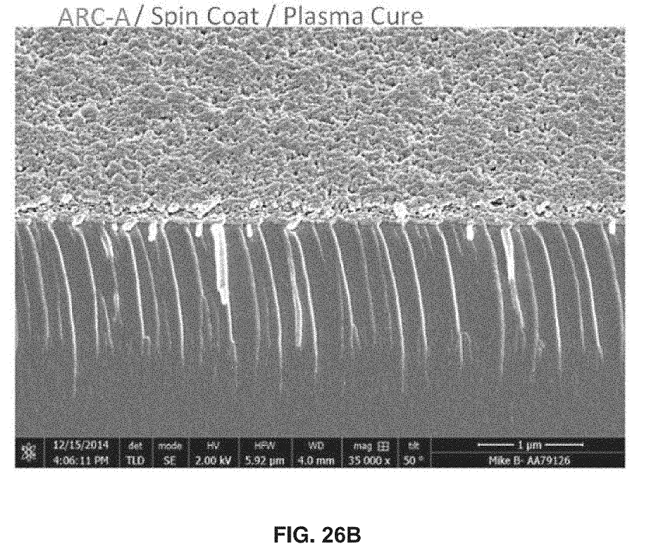

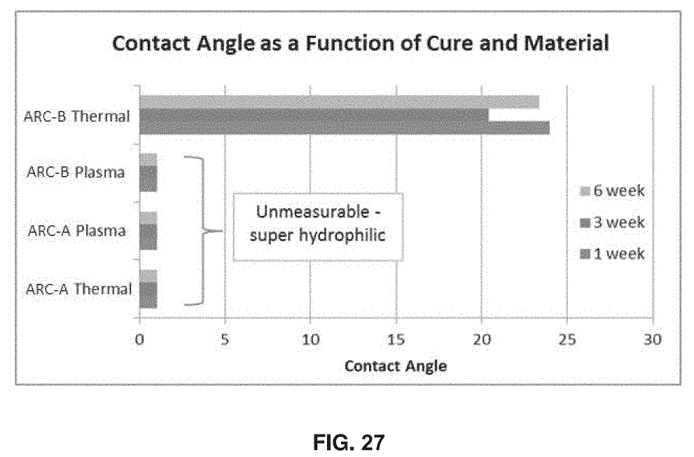

There are several surprising results that occur from plasma curing of ARCs. SEM imaging of plasma-cured ARCs show an unexpected difference from that of thermally cured ARCs. (FIGS. 25A, 25B, 26A, and 26B.) The contact angle appears to stay the same over time (FIG. 27), and the surface energy is unchanged over time, both of which is unexpected. Furthermore, in some embodiments, plasma curing is able to retain super hydrophobic functionality for a reasonably long time (FIG. 27), which is also surprising. These are all indications of superior ARC quality following plasma curing.

Photovoltaic Modules

The methods can be utilized to manufacture a photovoltaic module from any type of suitable solar cell semiconductor. These include, but are not limited to, CdTe-based semiconductors (for instance, those having a rectifying junction between p-type or high resistivity CdTe and doped or undoped n-type CdS, or those having a CdSeTe absorber layer and no window layer); C—Si, a-Si, GaAs, CIGS, and organic PV modules. Thus, further provided herein are photovoltaic modules produced by the methods described.

Referring now to FIG. 1, a typical ARC in a photovoltaic module 100 provides a porous silica coating layer 120 on top of a glass support 140, the glass support 140 being on top of a solar cell semiconductor 160. The glass support 140 may be soda-lime glass, low-iron glass, borosilicate glass, flexible glass, or other type of glasses or transparent substrates such as crystalline oxides and optical plastics. One non-limiting example of such an ARC is a colloidal suspension of silica particles in a solvent, such as water, an alcohol, or mixtures thereof. The suspension can include organic compounds in various forms and for various purposes, such as compounds designed to prevent the particles in suspension from clinging together. Generally, the ARC is applied while wet to the surface 180 of glass through any suitable method such as, but not limited to, roll-coating, dip-coating, spin coating, spray coating, wire rod coating, doctor blade coating, meniscus coating, slot die coating, capillary coating, curtain coating, or extrusion. Among the various ways of depositing the ARC films, spin casting or roller coating of ARC solution is the most economically viable. This is readily incorporated at any step of solar cell module fabrication.

After the coating process, a substantial amount of the solvent rapidly evaporates, usually within a few seconds (for example, up to about 5 seconds), leaving a substantially dry coating 120 on the surface 180 of the glass. This glass surface 180 is nonetheless hydrated, as the dry coating 120 is weakly bound to the surface 180 of the glass through SiOH bonds. A curing process as described herein is then conducted on the dry coating. In the case of a Si-based sol-gel coating, the curing process condenses the SiOH to yield water and SiO₂, leaving the film well adhered to the glass surface. Also during this process, any remaining solvent and residual organic compounds are driven off or evaporated. The result is a much stronger coating of SiO₂ on the glass surface 180. Such a SiO₂ coating 120 can be of many different thicknesses, such as from about 1 nm to about 900 nm, or from about 50 nm to about 500 nm, or from about 75 nm to about 200 nm. In one non-limiting example, the SiO₂ coating 120 is about 100 nm thick.

In the exemplary embodiment depicted in FIG. 1, the incoming or incident light from the sun or the like is first incident on the ARC 120, passing through the ARC 120 and then through the glass support 140 before reaching the solar cell semiconductor 160. The photovoltaic module 100 may further include, but does not require, additional layers such as, but not limited to, a reflection enhancement oxide, a transparent conductive oxide, a high resistance buffer, a window layer, and a back metallic or otherwise conductive contact and/or reflector. The ARC may reduce reflections of the incident light and permit more light to reach the solar cell semiconductor 160, thereby permitting the photovoltaic module 100 to act more efficiently.

Though Si-based sol-gels are described for illustrative purposes, other sol-gel ARCs can be used in any of the curing processes described herein. The ARCs can be provided in the form of sol-gel precursor solutions that are applied to the glass support and then cured. Sol-gel precursors include, but are not limited to, metal and metalloid compounds having a hydrolysable ligand that can undergo a sol-gel reaction to form a sol-gel. Suitable hydrolysable ligands include, but are not limited to, hydroxyl, alkoxy, halo, amino, or acylamino groups. Silica is the most common metal oxide participating in the sol-gel reaction, though other metals and metalloids can also be used, such as, but not limited to, zirconia, vanadia, titania, niobium oxide, tantalum oxide, tungsten oxide, tin oxide, hafnium oxide, alumina, or mixtures or composites thereof having metal oxides, halides, or amines capable of reacting to form a sol-gel. Additional metal atoms that can be incorporated into the sol-gel precursors include magnesium, molybdenum, cobalt, nickel, gallium, beryllium, yttrium, lanthanum, tin, lead, and boron. In certain non-limiting examples, the precursors are silicon alkoxides, such as tetramethylorthosilane (TMOS), tetraethylorthosilane (TEOS), fluoroalkoxysilane, or chloroalkoxysilane; germanium alkoxides, such as tetraethylorthogermanium (TEOG); vanadium alkoxides; aluminum alkoxides; zirconium alkoxides; and titanium alkoxides. In some embodiments, the precursor is an alkoxide of silicon, germanium, aluminum, titanium, zirconium, vanadium, or hafnium, or mixtures thereof. Examples of such metal alkoxides include, but are not limited to, tetraethoxysilane, tetraethyl orthotitanate, and tetra-n-propyl zirconate. The sol-gel precursor can be in a solution that includes one or more acid or base catalysts for controlling the rates of hydrolysis and condensation. Non-limiting examples of suitable catalysts include hydrochloric acid, nitric acid, sulfuric acid, acetic acid, ammonium hydroxide, and tetramethylammonium hydroxide.

In a non-limiting example of the method described herein, an ARC precursor solution is laid down wet, with about 10% solids and 90% solvent, on a glass support on top of a solar cell semiconductor. In other embodiments, the ARC precursor solution has a solids content as low as about 1%, with up to about 99% solvent. A substantial amount of the solvent is allowed to evaporate over a short period of time, up to about five seconds, thereby leaving a substantially dry coating on the surface of the glass support. The substantially dry coating is then subjected to curing through one of the methods described herein. The curing removes most, if not all, solvent remaining in the pores of the coating, removes organic compounds in the pores of the coating, and causes chemical reactions between adjacent particles in the coating, causing the adjacent particles to chemically bond together and to the glass surface.

Additionally, non-sol-gel ARCs are also encompassed within this disclosure. Suitable non-sol-gel ARCs include, but are not limited to, acrylates, methacrylates, epoxides, hybrid silicone-organic polymers, urethanes, fluoropolymers, silicones, and polysilazanes. Certain polymers can be used “as is” to form an ARC; that is, an organic polymer can be dissolved in a solvent to form a polymer solution that is applied to the glass support and then cured via one of the methods described herein. Curing can result in cross-linking and polymerization between organic monomers to form organic polymers such as acrylic polymers.

There are many ARCs that are commercially available. Any ARC may also include an additive such as a porogen, which assists or enhances pore formation so as to ensure the cured coating is porous or enhance the porosity of the cured coating. Suitable porogens include, but are not limited to, polymers, surfactants, or water-immiscible solvents. The porogen can be removed during drying or pyrolized during the curing process. In certain embodiments, the ARC includes a porogen selected from the group consisting of: polyethers, polyacrylates, aliphatic polycarbonates, polyesters, polysulfones, polystyrene, star polymers, cross-linked polymeric nanospheres, block copolymers, hyperbranched polymers, polycaprolactone; polyethylene terephthalate; poly(oxyadipoyloxy-1,4-phenylene); poly(oxyterephthaloyloxy-1,4-phenylene); poly(oxyadipoyloxy-1,6-hexamethylene); polyglycolide, polylactide (polylactic acid), polylactide-glycolide, polypyruvic acid, polycarbonate such as poly(hexamethylene carbonate) diol having a molecular weight from about 500 to about 2500, polyether such as poly(bisphenol A-co-epichlorohydrin) having a molecular weight from about 300 to about 6500, poly(methylmetacrylate), poly-gylcolids, polylactic acid, poly(styrene-co-α-methylstyrene, poly(styrene-ethyleneoxide), poly(etherlactones), poly(estercarbonates), poly(lactonelactide), hyperbranched polyester, polyethylene oxide, polypropylene oxide, ethylene glycol-poly(caprolactone), polyvinylpyridines, hydrogenated polyvinyl aromatics, polyacrylonitriles, polysiloxanes, polycaprolactams, polyurethanes, polydienes, hydrogenated polyvinyl aromatics, polyacrylonitriles, polysiloxanes, polycaprolactams, polyurethanes, polydienes, polyvinyl chlorides, polyacetals, amine-capped alkylene oxides, polyisoprenes, polytetrahydrofurans, polyethyloxazolines, polyalkylene oxide, a monoether of a polyallylene oxide, a diether of a polyalkylene oxide, bisether of a polyalkylene oxide, an aliphatic polyester, an acrylic polymer, an acetal polymer, a poly(caprolactone), a poly(valeractone), a poly(methlymethoacrylate), a poly(vinylbutyral), unfunctionalized polyacenaphthytene homopolymer, functionalized polyacenaphthylene homopolymer, polynorbornene, and combinations thereof.

### Examples

### Example 1—Air Knife Curing

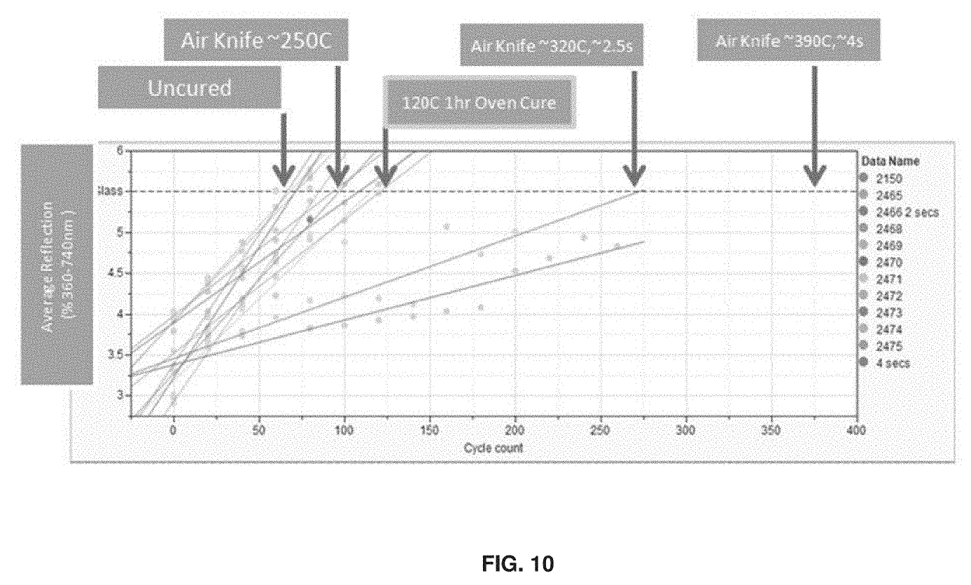

FIG. 10 shows the average reflection of films cured by parking an air knife for different times from 1 to 10 seconds over uncured films. Films were cured by parking the air knife for different times (1-10 seconds) over modules coated with an uncured ARC (referred to herein as ARC-C) coating. An air flow velocity of 80 m/s and an air temperature of 750° C. were used for this example. The air knife was parked at a height of 20 mm above the modules. Abrasion tests were performed to demonstrate curing. An abrasion tester was set up with a CS10F pad to apply a constant 14 N normal force to the abrasion disk during testing, with the pad “refaced” before each sample. The cured ARCs required multiple times more abrasion cycles to remove than the uncured ARCs. The cured ARCs also became harder at a slightly lower temperature. As seen from FIG. 10, the films can be made at least seven times stronger by achieving higher peak temperature for a short time.

### Example 2—Solder Wave Curing

A soldering station with a molten tin solder was utilized to cure ARCs on glass coupons. The soldering station was a modular wave soldering system having a standard solder pot with two waves, a turbulent “chip wave” and a smoother “lambda wave.” The modular unit had three preheat stations which were IR or hot air convection stations. The coupons were passed through the soldering station to cure the ARC coatings.

In order to determine the thermal shock limit of the glass used in photovoltaic modules, 30×30 scrap glass was run first at 12 ft/min over a 3 inch-wide contact wave solder. No breakage occurred. The speed was dropped to 3 ft/s, and the glass cracked with a contact time above 3.5 seconds. A preheat of 75° C. was added, and the speed was increased to 3.9 ft/s, and no further cracking was observed after several runs. The operational boundaries for breakage and temperature were then determined. The glass thermal shock limit was determined to be a contact time of 3.5 seconds and a solder temperature of 290° C.

ARC-coated glass was contacted by the solder wave for a time period of 1 second. The measured temperature after a 75° C. preheat and the wave contact was 110° C., as measured with an IR camera (e=0.90). Solder stuck on the glass surface and on the AR coating when the process was performed in air. The first trials sent glass over the wave in ambient air. Small globs of oxidized solder clung to the panelSolder sticking to the glass surface was visible as white “scratch”-looking spots. A nitrogen purge was then turned on. As soon as this was done, the panels came out clean, without any globs of oxidized solder clinging to them. The plates were wiped with water or sent through “as received.” Neither approach caused solder to cling to the ARC when under nitrogen. ARC-D, ARC-C (30×30 cm), and ARC-E (10×10 cm coupon) samples were run with N₂, and no solder sticking was observed.

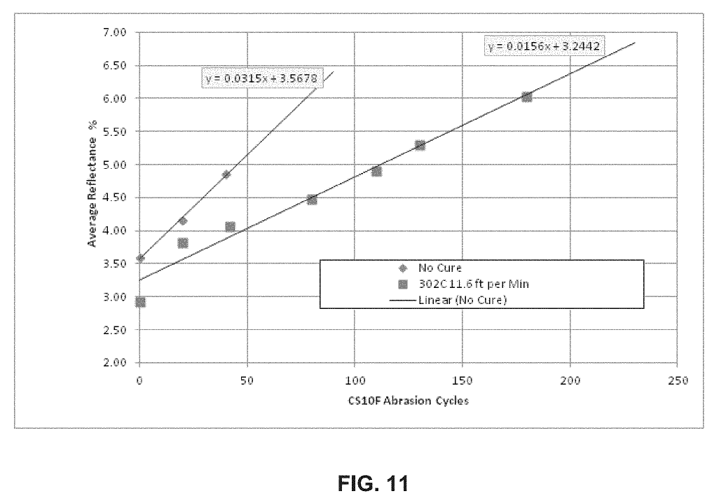

An abrasion test was then conducted to demonstrate the curing. An abrasion tester was set up to apply a constant normal force to the abrasion disk during testing. FIG. 11 shows the abrasion data from the solder wave curing of the ARC on a full photovoltaic module. Before and after cure measurements were taken in the same location. As seen in FIG. 11, abrasion resistance improved to match or even exceed that obtained from oven curing.

Kapton tape and aluminum foil were used to thermally insulate the glass, making an uncured spot. The area thermally masked by the tape or tape over aluminum foil fell off after ˜25 manual abrasion cycles, leaving an image of the tape, indicating that the cure worked.

5 ARC-C films were cured. ARC-E and ARC-D samples (10×10 cm) were run to evaluate whether solder sticks on them or dissolves the coating. No obvious problems were noted. The coatings remained with no obvious signs of chemical attack visible. The following table summarizes the test cure conditions utilized in this example:

TABLE 2
Summary of test cure conditions

| | Target Out | Actual out IR | IR Temp HI | Translation | Solder Pot | |
|---|---|---|---|---|---|---|
| Sample Name | Temp (C.) | Temp Lo (C.) | (C.) | Speed (ft/min) | Temp. (C.) | Preheat |
| Scrap glass | 80 | 77 | 80 | 3.6 | 270 | none |
| ARC-C1 | 80 | xxx | xxx | 3.6 | 290 | none |
| ARC-C2 | 120 | 105 | 110 | 3.9 | 290 | convection to 70 C. |
| ARC-C3 | 120 | | 110 | 3.9 | — | — |
| ARC-C4 | 110 | 103 | 108 | 4.4 | — | — |
| ARC-C2 | 90 | | | 6.6 | — | — |
| ARC-C2 | 75 | | | 10?? | — | — |
| Older ARC-C | 110 | 105 | 110 | 3.9 | — | — |
| zuncuredARC-E | 100 | | | 4.4 | — | — |
| ARC-E1 | 110 | | | 4.4 | — | — |
| ARC-E2 | 110 | 105 | | 4.4 | — | — |
| ARC-F 10 × 10 | 110 | | | 4.4 | — | — |
| ARC-F2 | XXX | | | | — | — |
| ARC-F3 | | | | | — | — |

### Example 3—Plasma Curing

To demonstrate plasma curing, a 5×5 cm² sample was utilized. An ARC-A solution was spin-coated onto FS200 coupons/R-cells 4-layer stacks. Among the different rotation speeds tested, 1500 rpm for 5 s appeared to result in the desired thickness of the ARC-A solution.

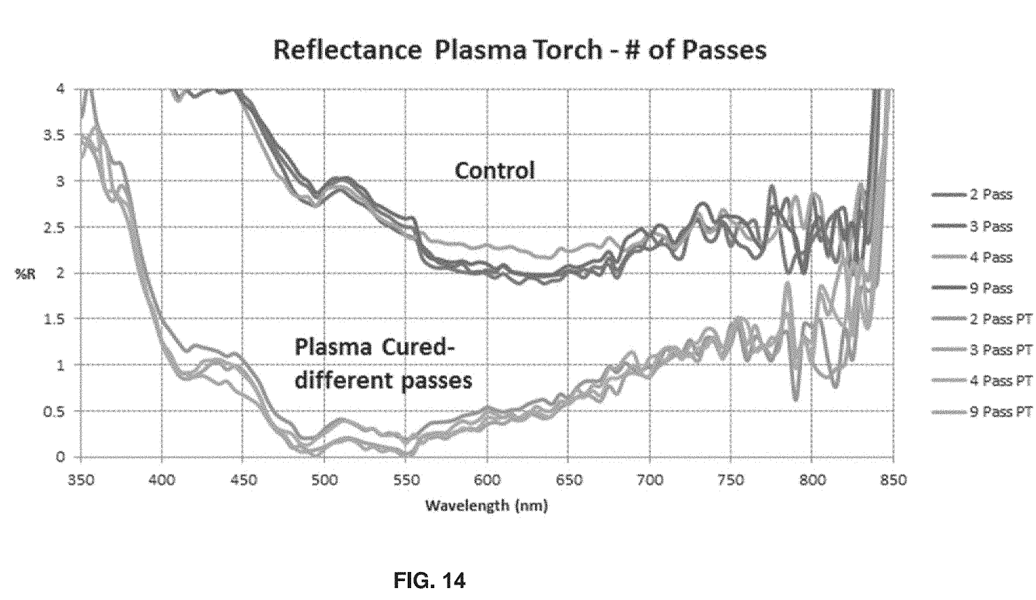

The coupons were exposed to a plasma torch for varying numbers of passes to cure the ARC. The lowest reflectance of about 0.2% at 600 nm was observed after 3 passes. (FIG. 14.) A thermocouple was also placed on the film-side to measure the increase in temperature. After three passes, the film-side temperature went up to 100° C. As seen from FIG. 14, each of the plasma cured ARCs exhibited a lower reflectance than the uncured control ARCs.

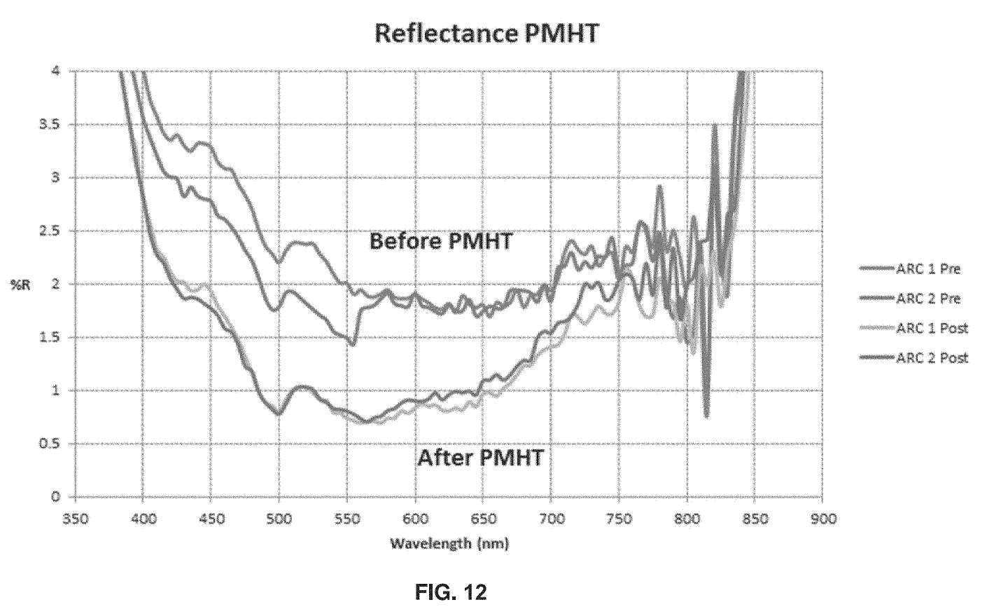

Plasma curing was tested with the ARC-A both before conducting a post-manufacturing heat treatment (PMHT) on litho-processed PV devices and after conducting the PMHT. (FIG. 12.) Many cells with improved J_{sc}QE were observed. These were fresh devices that awoke to very high performing cells with an improved effective quantum efficiency. FIG. 12 depicts reflectance versus wavelength for two different plasma torch-cured ARCs pre- and post-PMHT. As seen from FIG. 12, the percent reflectance of both ARCs was reduced when the films were cured following the PMHT.

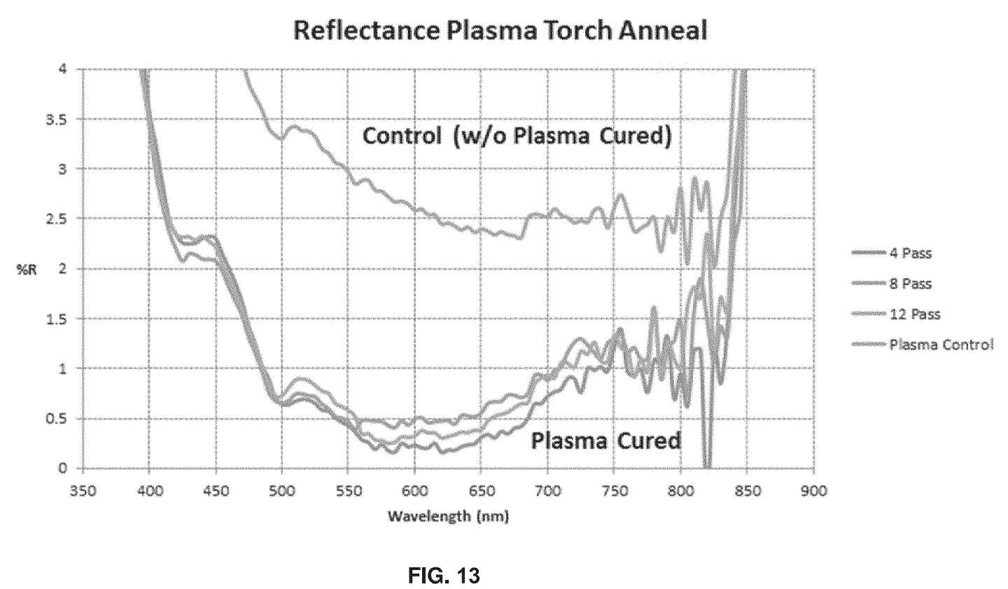

FIG. 13 depicts reflectance versus wavelength for films cured with 4, 8, or 12 passes of a plasma torch, compared to an uncured ARC control. As seen from FIG. 13, for much of the visible spectrum, the ARC cured with 4 passes of a plasma torch exhibited the lowest reflectance. All of the plasma torch-cured ARCs exhibited lower reflectance compared to the uncured control ARC. FIG. 13 further demonstrates that excessive passes of the plasma torch can deteriorate the anti-reflectance properties of an ARC.

This example shows the benefits of plasma curing as against the PMHT temperature and duration induced curing of ARC films. From FIG. 12-14 it can be seen that plasma curing is a superior ARC curing method.

### Example 4—Plasma Curing

Plasma curing with a spinning plasma torch on an X-Y mapper was evaluated with device coupons having an ARC-A or a ARC-B coating on a T185 glass substrate. The curing time and temperature, coating thickness, distance between the plasma torch and substrate, and the X-Y mapper speed were held constant. The plasma-cured films were compared to films cured by thermal curing in a box furnace for 30 minutes at 275° C.

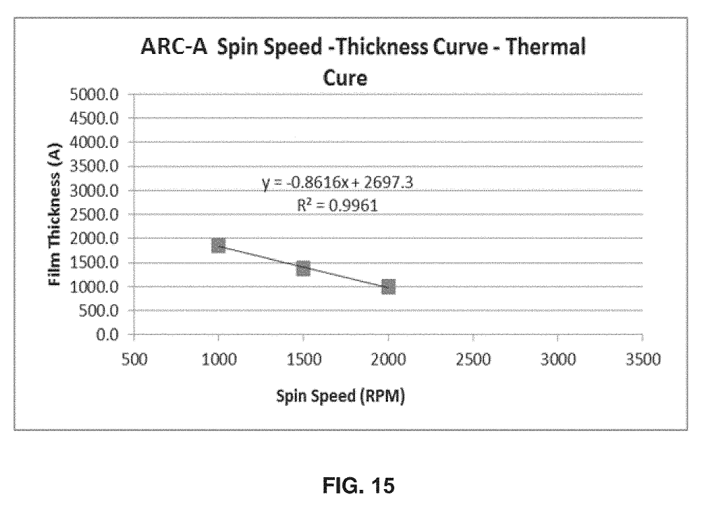

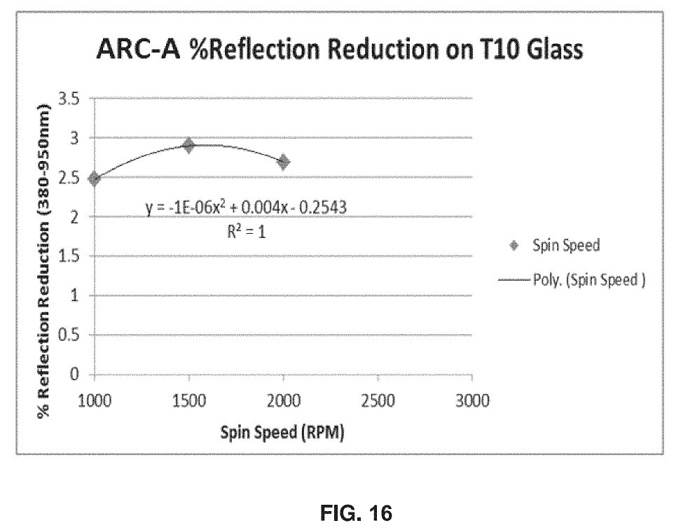

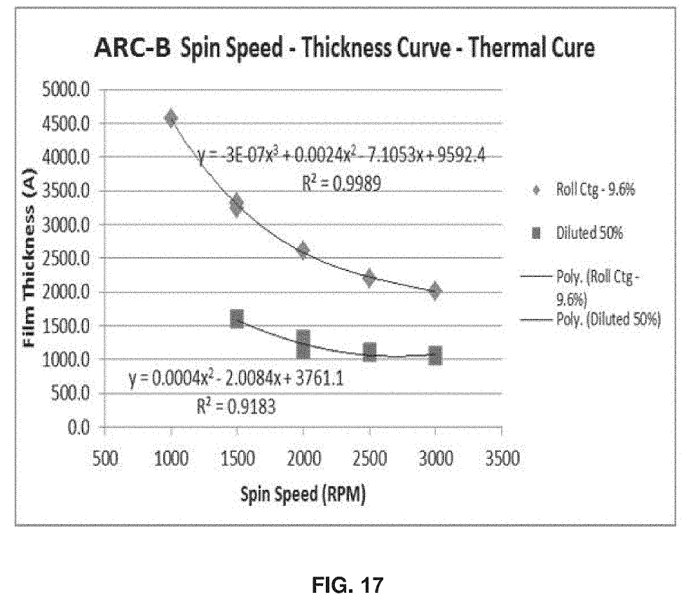

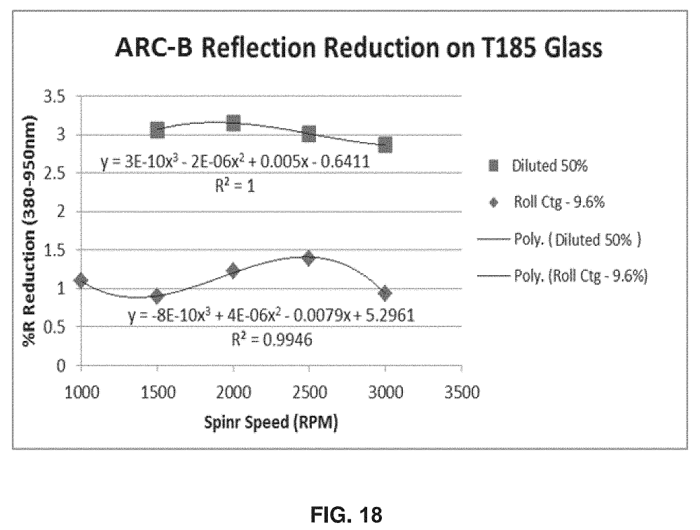

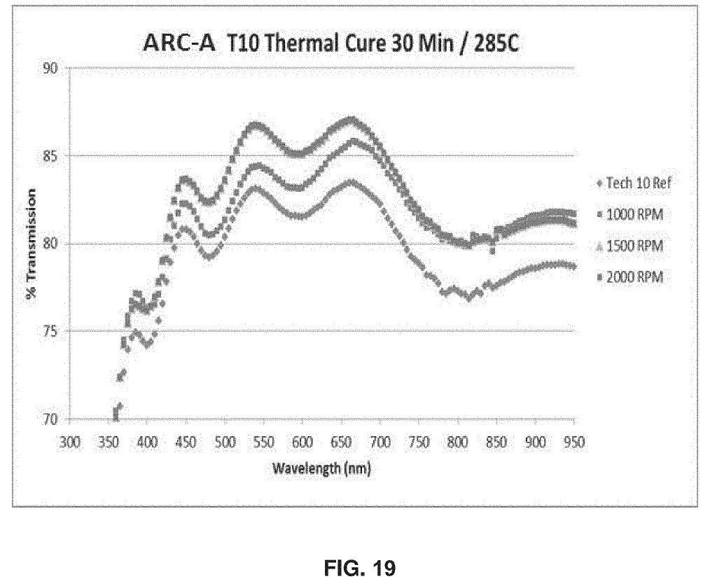

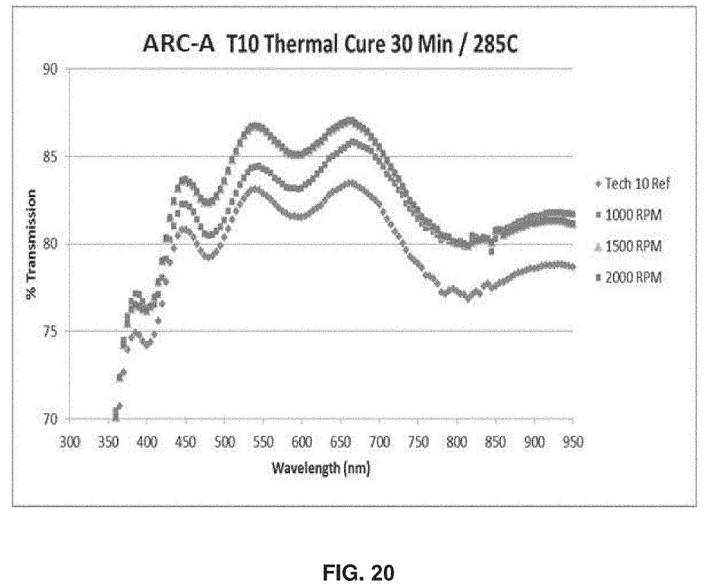

First, the film thickness was optimized. The ARC-A solution optimum coating was at 1500 Å. (FIGS. 15-16.) The ARC-B formulation, which is designed for a roll coat process, was used at 9.6% solids. 50% dilution of ARC-B was needed to achieve comparable reflection performance. The optimum spin speed of the ARC-B coating was 2000 rpm at 50% dilution. (FIGS. 17-18.) ARC-A films showed little performance difference between 1500-2000 rpm (FIG. 19), while the ARC-B films showed comparable performance with spin speeds between 2000-3000 rpm (FIG. 20).

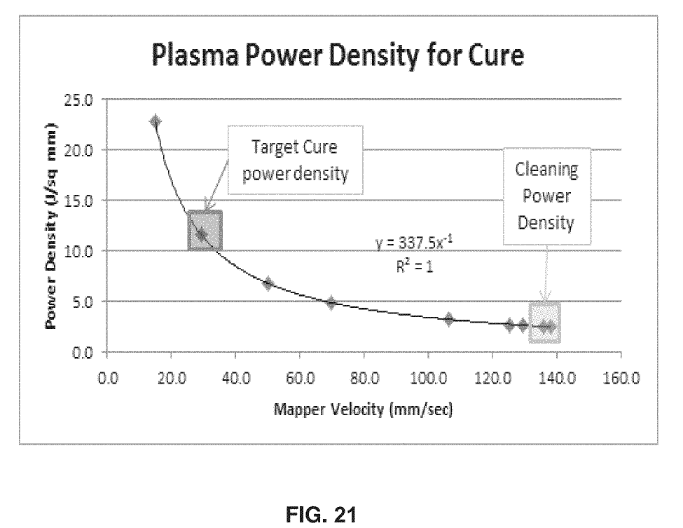

For the plasma curing, an 18 KV, 0.3 amp, 5.4 KW torch was used. The plasma torch delivered plasma in an annulus ring. As seen in FIG. 21, the cure power density was 3.6 times higher than the cleaning plasma density. A line speed of 1 in./sec (25.3 mm/sec) with 4 passes resulted in the best condition.

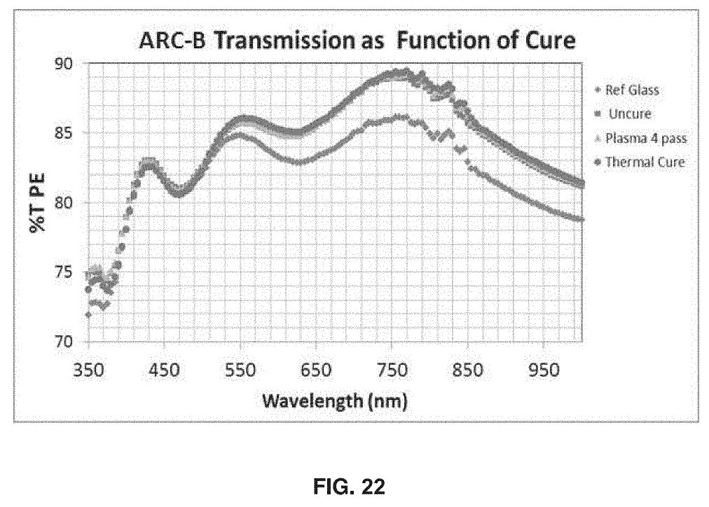

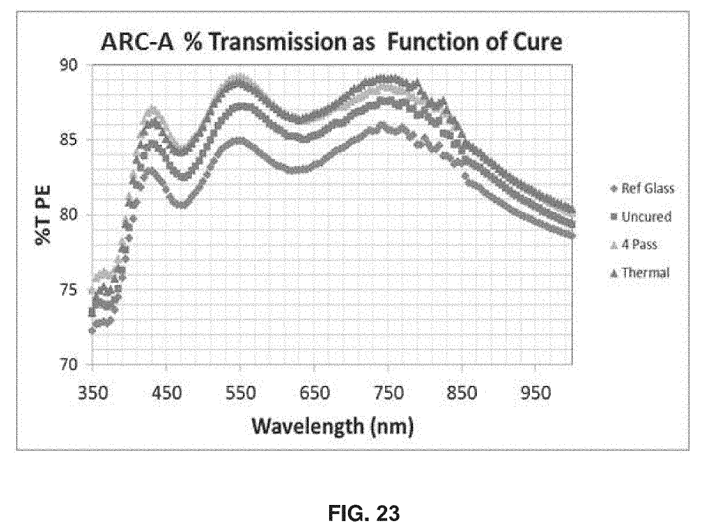

ARC-A and ARC-B samples were cured via thermal (30 minutes at 275° C.) and plasma (4 passes) on T185 glass. The % transmission curves between the two types of films were significantly different. (FIGS. 22-23.) ARC-B % transmission was lower than the optimum thickness. ARC-B optics exhibited little change with curing, either plasma or thermal. (FIG. 22.) Without wishing to be bound by theory, it is believed this is because optics are geometry-dependent. The ARC-A optics, on the other hand, changed with both thermal and plasma curing. The thermal and plasma curing were comparable; a significant binder effect was demonstrated with both. (FIG. 23.)

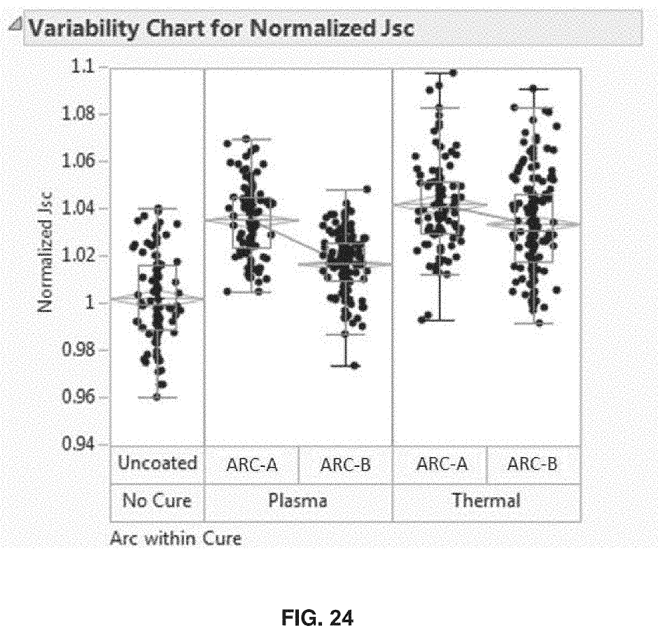

As seen from Tables 3 and 4 below, and FIG. 24, a low temperature plasma process provides adequate cure to achieve good optical performance for ARC-A. The ARC-A film can achieve comparable optical performance to ARC-B. (FIG. 24.)

TABLE 3
QE Evaluation

| ARC | Cure | % Current |
|---|---|---|
| Ref Cell | PMHT | Gain |
| ARC-A | Thermal | 3.70% |
| ARC-A | Plasma | 3.30% |
| ARC-B | Thermal | 2.10% |
| ARC-B | Plasma | 2.10% |

TABLE 4
I-V Characterization

| ARC | Cure | % Current |
|---|---|---|
| Ref Cell | PMHT | Gain |
| ARC-A | Plasma | 3.70% |
| ARC-A | Thermal | 4.30% |
| ARC-B | Plasma | 1.80% |
| ARC-B | Thermal | 3.50% |

SEM imaging was conducted on the plasma-cured films. For the ARC-B solution, diluting 50% with PGME achieved desired thickness. Large spherical silica particles were clear nominally in 100 nm in diameter. Little difference was seen between the plasma-cured and thermal-cure ARC-B films. (FIGS. 25A-25B.) For the ARC-A solution, the film was textured with an irregular patterned surface. There was a significant difference between plasma-cured and thermal-cured ARC-A films. (FIGS. 26A-26B.) The plasma-cured film was significantly smoother. The plasma curing also produced permanent super hydrophilic surfaces for some of the ARC films. (FIG. 27.)

Without wishing to be bound by theory, it is believed that the performance of the ARC-B film is based on geometric design with large silica spheres and a small portion of binder, with little porosity. ARC-B optical performance is not significantly affected by curing. Curing of an ARC-B film is mainly needed to obtain durability. An ARC-A film, on the other hand, is an irregular rough surface structure film, and the anti-reflective properties of the film are most likely due to a combination of porosity in the bulk of the film and surface topography. As shown in this example, plasma curing provides adequate curing to achieve good optical performance for ARCs such as ARC-A. The SEM images show differences in thermal versus plasma curing on film topography. The ARC-A film can achieve optical performance comparable to the ARC-B film. Moreover, the fact that plasma curing imparts a long-lasting hydrophilic surface is high unexpected, and makes plasma curing useful as a curing method for other types of coatings.

### Example 5—Flame Curing

A flame was used to cure ARC films on finished photovoltaic modules. The flame produced a surface temperature of about 300° C. for 0.5 seconds. According to IR data, a final temperature of 90° C. after equilibration was sufficient to cure the film.

In some embodiments, a method of curing an anti-reflective coating on a sunny side of TCO-coated superstrate glass having a preformed thin film PV module thereon can include exposing an uncured anti-reflective coating on the glass to a hot air knife, an impinging flame, a liquid metal, or a plasma, to cure the anti-reflective coating on the glass.

In some embodiments, a method of curing an anti-reflective coating on glass can include exposing an uncured anti-reflective coating on glass to a hot air knife, an impinging flame, a liquid metal, or a plasma, to cure the anti-reflective coating on the glass. Alternatively or additionally, the glass can include a glass support in a photovoltaic module. Alternatively or additionally, the glass can include soda-lime glass, low-iron glass, borosilicate glass, flexible glass, crystalline oxides, or optical plastics. Alternatively or additionally, the uncured anti-reflective coating can include a suspension of silica particles in a solvent. Alternatively or additionally, the cured anti-reflective coating can have at least twice the hardness as the uncured anti-reflective coating.

In some embodiments, a method of curing an anti-reflective coating on glass can include contacting an uncured anti-reflective coating on glass with a liquid metal to cure the anti-reflective coating on the glass. Alternatively or additionally, the glass can include a glass support in a photovoltaic module. Alternatively or additionally, the liquid metal can include a material having a convection coefficient greater than 4000 W/m²K. Alternatively or additionally, the liquid metal can include liquid tin. Alternatively or additionally, the liquid tin can be or can include pure tin. Alternatively or additionally, the liquid metal can include a eutectic solder selected from the group consisting of: Sn/Ag, Sn/Sb, Sn/In, Sn/Zn, Sn/Bi, Sn/Pb/Ag, Sn/Bi/Sb, Sn/Ag/Cu, and Sn/Bi/In. Alternatively or additionally, the contacting can be conducted under an inert atmosphere. Alternatively or additionally, the inert atmosphere can include nitrogen, helium, argon, or a combination thereof. Alternatively or additionally, the method can include at least one preheat step prior to contacting the uncured anti-reflective coating with the liquid metal. The at least one preheat step can include heating the glass by IR or convection.

In some embodiments, a method of curing an anti-reflective coating on glass can include exposing an uncured anti-reflective coating on glass to hot air at a sufficient temperature, speed, and duration to cure the anti-reflective coating on the glass. The hot air can be blown through an air knife. Alternatively or additionally, the glass can include a glass support in a photovoltaic module. Alternatively or additionally, the air knife can include a nozzle for ejecting the hot air, the nozzle having a diameter ranging from about 2 to about 20 mm wide. Alternatively or additionally, the uncured anti-reflective coating on glass can be exposed to the hot air for a duration ranging from about 1 second to about 60 seconds to cure the anti-reflective coating on the glass. Alternatively or additionally, the hot air can have a convection coefficient ranging from about 200 W/m²K to about 400 W/m²K.

In some embodiments, a method of curing an anti-reflective coating on glass can include exposing an uncured anti-reflective coating on glass to a plasma to cure the anti-reflective coating on the glass. Alternatively or additionally, the glass can include a glass support in a photovoltaic module. Alternatively or additionally, the plasma can be generated from a plasma torch. Alternatively or additionally, the plasma torch can be a DC current plasma torch. Alternatively or additionally, the plasma torch can be a transferred arc torch. Alternatively or additionally, the plasma torch can be a non-transferred arc torch. Alternatively or additionally, the method can include moving the plasma torch up or down relative to the glass. Alternatively or additionally, the method can include repeating the exposing step. Alternatively or additionally, the glass can be subjected to a heat treatment before the uncured anti-reflective coating is exposed to the plasma. Alternatively or additionally, the glass can be part of an existing photovoltaic module.

In some embodiments, a method of curing an anti-reflective coating on glass can include exposing an uncured anti-reflective coating on glass to an impinging flame to cure the anti-reflective coating on the glass. Alternatively or additionally, the glass can be a glass support in a photovoltaic module.

In some embodiments, a method of assembling a photovoltaic module can include providing a glass support over a solar cell semiconductor. The method can further include coating the glass support with a wet anti-reflective coating to produce a coated glass surface. The anti-reflective coating can include a suspension of particles in a solvent. The method can further include allowing a substantial amount of the solvent to evaporate. A substantially dry anti-reflective coating can be formed on the glass surface. The method can further include exposing the substantially dry anti-reflective coating to a curing process for a sufficient amount of time to cure the anti-reflective coating on the glass support and produce a photovoltaic module. The curing process can be selected from the group consisting of liquid metal curing, air knife curing, plasma curing, and flame curing. Alternatively or additionally, the wet anti-reflective coating can include about 1% solids and about 99% solvent.

Certain embodiments of the systems, methods, and photovoltaic modules disclosed herein are defined in the above examples. It should be understood that these examples, while indicating particular embodiments of the invention, are given by way of illustration only. From the above discussion and these examples, one skilled in the art can ascertain the essential characteristics of this disclosure, and without departing from the spirit and scope thereof, can make various changes and modifications to adapt the compositions and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

What is claimed is:

1. A method of assembling a photovoltaic module, the method comprising:
providing a glass support over a solar cell semiconductor;
coating the glass support with a wet anti-reflective coating to produce a coated glass surface, the anti-reflective coating comprising a suspension of particles in a solvent;
allowing a substantial amount of the solvent to evaporate, thereby forming a substantially dry anti-reflective coating on the glass surface; and
exposing the substantially dry anti-reflective coating to a curing process selected from the group consisting of liquid metal curing, air knife curing, plasma curing, and flame curing, for a sufficient amount of time to cure the anti-reflective coating on the glass support and produce a photovoltaic module.

2. The method of claim 1, the wet anti-reflective coating comprising about 1% solids and about 99% solvent.

3. A method of curing an anti-reflective coating on a sunny side of TCO-coated superstrate glass having a preformed thin film PV module thereon, the method comprising exposing an uncured anti-reflective coating on the glass to a hot air knife, an impinging flame, a liquid metal, or a plasma, to cure the anti-reflective coating on the glass.

4. A method of curing an anti-reflective coating on glass, the method comprising exposing an uncured anti-reflective coating on glass to a hot air knife, an impinging flame, a liquid metal, or a plasma, to cure the anti-reflective coating on the glass.

5. The method of claim 4, the glass being a glass support in a photovoltaic module.

6. The method of claim 4, wherein the glass comprises soda-lime glass, low-iron glass, borosilicate glass, flexible glass, crystalline oxides, or optical plastics.

7. The method of claim 4, the uncured anti-reflective coating comprising a suspension of silica particles in a solvent.

8. The method of claim 4, the cured anti-reflective coating having at least twice the hardness as the uncured anti-reflective coating.

9. A method of curing an anti-reflective coating on glass, the method comprising contacting an uncured anti-reflective coating on glass with a liquid metal to cure the anti-reflective coating on the glass.

10. The method of claim 9, wherein the glass is a glass support in a photovoltaic module.

11. The method of claim 9, wherein the liquid metal comprises a material having a convection coefficient greater than 4000 W/m²K.

12. The method of claim 9, wherein the liquid metal comprises liquid tin.

13. The method of claim 12, wherein the liquid tin comprises pure tin.

14. The method of claim 9, wherein the liquid metal comprises a eutectic solder selected from the group consisting of: Sn/Ag, Sn/Sb, Sn/In, Sn/Zn, Sn/Bi, Sn/Pb/Ag, Sn/Bi/Sb, Sn/Ag/Cu, and Sn/Bi/In.

15. The method of claim 9, wherein the contacting is conducted under an inert atmosphere.

16. The method of claim 15, wherein the inert atmosphere comprises nitrogen, helium, argon, or a combination thereof.

17. The method of claim 9, further comprising at least one preheat step prior to contacting the uncured anti-reflective coating with the liquid metal, wherein the at least one preheat step comprises heating the glass by IR or convection.
